(19) United States
(12) Patent Application Publication
(10) Pub. No.: US 2014/0261667 A1
(43) Pub. Date: Sep. 18, 2014

(54) PHOTOVOLTAIC DEVICE HAVING IMPROVED BACK ELECTRODE AND METHOD OF FORMATION

(71) Applicant: FIRST SOLAR, INC., Perrysburg, OH (US)

(72) Inventors: Benyamin Buller, Sylvania, OH (US); Igor Sankin, Perrysburg, OH (US); Long Cheng, Perrysburg, OH (US); Jigish Trivedi, Perrysburg, OH (US); Jianjun Wang, Perrysburg, OH (US); Kieran Tracy, Perrysburg, OH (US); Scott Christensen, Perrysburg, OH (US); Gang Xiong, Santa Clara, CA (US); Markus Gloeckler, Perrysburg, OH (US); San Yu, Perrysburg, OH (US)

(73) Assignee: FIRST SOLAR, INC., Perrysburg, OH (US)

(21) Appl. No.: 14/209,924

(22) Filed: Mar. 13, 2014

Related U.S. Application Data
(60) Provisional application No. 61/794,244, filed on Mar. 15, 2013.

(51) Int. Cl. H01L 31/0224; H01L 31/18

(52) U.S. Cl. CPC H01L 31/022441; H01L 31/1828
USPC 136/256; 438/94; 438/95

(57) ABSTRACT

A back electrode for a PV device and method of formation are disclosed. A ZnTe material is provided over an absorber material and a MoNₓ material is provided over the ZnTe material. A Mo material may also be included in the back electrode above or below the MoNₓ layer and a metal layer may be also provided over the MoNₓ layer.

This application claims the benefit of priority of U.S. Provisional Patent Application No. 61/794,244, filed Mar. 15, 2013, entitled: “Photovoltaic Device Having Improved Back Electrode and Method of Formation” the entirety of which is incorporated by reference herein.

### TECHNICAL FIELD

The invention relates generally to a photovoltaic (PV) device, which may include one or more photovoltaic modules, cells, or any device that converts light energy to electricity. In particular, the invention relates to a back electrode for a photovoltaic device, and a method for its formation.

### BACKGROUND

PV devices convert solar radiation (the energy of sunlight) into electrical current, a process known as the “photovoltaic effect.” Generally, a thin film PV device includes a front electrode and a back electrode sandwiching a series of semiconductor layers. The semiconductor layers provide a p-n junction. The semiconductor layers typically include an n-type semiconductor window layer in electrical communication with the front electrode and a p-type semiconductor absorber layer in electrical communication with the back electrode.

In order to increase the efficiency of the PV device in converting light into electricity, a back electrode which adheres well to the absorber layer and provides a low resistance ohmic contact path for current flow is desired.

### BRIEF DESCRIPTION OF DRAWINGS

FIG. 1 illustrates, in cross section, a first embodiment of a partially completed PV device with a back electrode;

FIG. 2 illustrates, in cross section, a second embodiment of a partially completed PV device with a back electrode;

FIG. 3 illustrates, in cross section, a third embodiment of a partially completed PV device with a back electrode;

FIGS. 4 and 4A illustrate a process for producing the FIG. 1 embodiment;

FIGS. 5 and 5A illustrate a process for producing the FIG. 2 embodiment; and

FIGS. 6 and 6A illustrate a process for producing the FIG. 3 embodiment.

FIG. 7 illustrates, in cross section, an embodiment of a partially completed PV device.

### DETAILED DESCRIPTION

Embodiments described herein provide a PV device having an improved back electrode which contacts with an absorber layer. An interface material formed of zinc telluride (ZnTe) or a copper-doped zinc telluride is in contact with the absorber layer. A back electrode includes molybdenum (Mo) and/or molybdenum nitride (MoNₓ) material in contact with the ZnTe or Cu-doped ZnTe interface material, and may also include a metal material in contact with the Mo and/or MoNₓ material. The back electrode can be employed in a PV device having semiconductor n-type window and p-type absorber layers. The n-type and p-type semiconductors can be formed from any Group II-VI, III-V or IV semiconductor, such as, for example, Si, SiC, SiGe, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AlN, AlP, AlAs, AlSb, GaN, GaP, GaAs, GaSb, InN, InP, InAs, InSb, InGaAs, TlN, TlP, TlAs, TlSb, or mixtures or alloys thereof. As one example, the window layer can be formed of CdS and the absorber layer can be formed of CdTe. Back electrodes having an interface material, a Mo and/or MoNₓ material and a metal material, have been found to have good adhesion to the absorber layer and provide a low resistance ohmic contact to the absorber layer, and can be easily integrated into existing PV device production facilities.

FIG. 1 illustrates a first embodiment. A partially fabricated PV device 101 is illustrated. It includes a substrate 201 which may be formed of glass, including, but not limited to, a soda lime glass, low Fe glass, solar float glass or other suitable glass. A barrier layer 203 which prevents components of the substrate 201 from entering into other material layers of PV device 101 that can be provided over the substrate 201. The barrier layer 203 can be formed of any suitable material, including, but not limited to, silica, alumina, tin oxide, or silicon aluminum oxide. In some instances the barrier layer can be omitted. A transparent conductive oxide (TCO) front electrode 205 is formed over the barrier layer 203. The TCO can be formed of any suitable transparent conductive oxide, including, but not limited to, indium gallium oxide, cadmium stannate, cadmium tin oxide, cadmium indium oxide, fluorine doped tin oxide, aluminum doped zinc oxide, or indium tin oxide. A buffer layer 207 can be provided over the TCO layer 205. The buffer layer 207 is useful in reducing recombination of holes and electrons at the interface of the TCO layer 205 and window layer. In some instances the buffer layer 207 can be omitted. The buffer layer 207 can be formed of any suitable material, including, but not limited to, tin oxide, zinc oxide, a mixture of tin and zinc oxides, zinc stannate, or zinc magnesium oxide.

The PV device further includes an n-type semiconductive window layer 209, which may be formed of cadmium sulfide (CdS) and a p-type absorber layer 211, which may be formed of cadmium telluride (CdTe). The CdTe absorber layer may also be doped with copper (CdTe:Cu)

As further shown in FIG. 1, an interface layer 213, which may be formed of zinc telluride (ZnTe) or a copper-doped zinc telluride is deposited on the absorber layer 211. The interface layer 213 may alternatively be formed of any other suitable interface materials, including, but not limited to, HgTe, Te, and PbTe. A back electrode layer 217, which may be formed of molybdenum nitride (MoNₓ), is deposited on the interface layer 213. A metal layer 231 may be deposited over the MoNₓ layer 215 as part of the back electrode 217. The metal layer may be formed of aluminum, copper, nickel, gold, silver, or chromium, or any other metals know to be useful as a PV device conductor. The ZnTe interface layer 213 provides a low contact resistance and a good adhesion layer to the absorber layer 211 and back electrode layer 217. If copper doping is employed for the interface layer 213, the Cu-doped ZnTe layer comprises about 0.1 to about 2.0 atomic percent Cu.

The manner in which the interface layer 213, MoNₓ layer 215 and metal layer 231 of back electrode 217 of the FIG. 1 structure is formed is more fully described with reference to FIGS. 4 and 4A. FIG. 4 illustrates a partially formed structure 401 which includes all material layers shown in FIG. 1 up to and including the absorber layer 211. The partially formed structure 401 may be first pre-cleaned to remove any contaminates or debris on the surface of the absorber layer 211. The partially formed structure 401 is conveyed through a series of processing chambers 403, 405, and 407. The first processing chamber 403 receives the partially formed structure 401 and forms the ZnTe or Cu-doped ZnTe interface layer on the absorber layer 211, which may be a CdTe or CdTe:Cu layer. Step 451 of the processing sequence shown in FIG. 4A. In the first processing chamber 403, the ZnTe (or Cu-doped ZnTe) material is formed by a deposition process known as sputtering. In general, sputtering involves the ejectment of atoms from the surface of a target material via energetic bombardment of ions on the surface of the target. Alternatively, the ZnTe (or Cu-doped ZnTe) may be formed by any other suitable deposition process known in the art, including, but not limited to, pulse laser deposition (PLD), chemical vapor deposition (CVD), electro-chemical deposition (ECD), atomic layer deposition (ALD), or vapor transport deposition (VTD). If Cu-doped ZnTe is to be formed, the ZnTe can be first deposited, for example, by sputtering a ZnTe target in an argon (Ar) or any other ionizing inert gas filled chamber. The argon (Ar) or any other ionizing inert gas ionizes readily and provides a high sputter yield. The deposition of ZnTe is then followed by a copper doping of the ZnTe material using any method known to those skilled in the art. For example, a solution of CuCl₂, or any other suitable wet solutions containing copper may be applied to the surface of the ZnTe. The amount of copper in solution may range from about 0.01 to about 1.0 mM. Following formation of the ZnTe (or Cu-doped ZnTe) interface layer 213, the ZnTe (or Cu-doped ZnTe) coated structure 401 passes into a gas separation chamber 405. Step 453 of FIG. 4A. The gas separation chamber 405 is designed to keep the processing of the ZnTe or Cu-doped ZnTe layer in chamber 403 separated from processing of the MoNₓ layer 215 in processing chamber 407. This prevents cross contamination of the processing conditions and materials in chambers 403 and 407.

In chamber 407, the MoNₓ layer 215 is formed by sputtering. The MoNₓ layer 215 may alternatively be formed by any other suitable deposition process known in the art, including, but not limited to, pulse laser deposition (PLD), chemical vapor deposition (CVD), atomic layer deposition (ALD), or vapor transport deposition (VTD). The MoNₓ layer 215 is formed, for example, by sputtering a molybdenum (Mo) target in an argon (Ar) or other ionizing inert gas, and nitrogen (N₂) gas environment. The argon (Ar) or other ionizing inert gas is utilized because it ionizes readily and provides a high sputter yield. The nitrogen (N₂) gas is used because it allows for the formation of nitrides, which provides a better diffusion barrier and contact. The argon (Ar), or other ionizing inert gas, and nitrogen (N₂) can be introduced into processing chamber 407 as two independent gas sources of Ar and N₂, which enables a wide range of Ar/N₂ ratios for the MoNₓ deposition. The argon (Ar) or other ionizing inert gas, and nitrogen (N₂) gas can also be pre-mixed to contain a known ratio of Ar/N₂ prior to introduction into the processing chamber 407. For instance, a pre-mixed gas bottle containing Ar and N₂ with a known ratio of Ar/N₂ can be connected to the processing chamber 407. The temperature employed in processing chamber 407 for deposition of the MoNₓ layer 215 can be in the range of room temperature to 300° C. The power applied to the Mo chamber 207 for the sputtering deposition, which can be either DC or pulsed DC, can be in the range of about 8 kW to about 12 kW. The power provides the necessary energy to ionize the Ar and N₂ gas sources. The argon (Ar) to nitrogen (N₂) ratios (Ar/N₂) can range from about 30 percent N₂ to about 80 percent N₂ to create an MoNₓ structure. Depending on the Ar/N₂ ratio used, MoNx may include Mo₃N₂, Mo₂N, and/or MoN. The resultant MoNₓ layer has a sheet resistance in the range of 180-250 ohm-sq. After exiting chamber 407, the coated partially completed PV device 401 may proceed to another chamber 409 for deposition of a metal layer 231 over the MoNₓ layer. The metal layer may be aluminum, copper, nickel, gold, silver, or chromium, or any other metals know to be used as an electrode in PV devices.

FIG. 2 illustrates a second embodiment of a PV device 103, while FIGS. 5 and 5A, respectively illustrate the processing chambers and process sequence for producing the FIG. 2 embodiment.

Referring first to FIG. 2, each of the materials from substrate 201 through interface layer 213 are the same as described above with reference to FIG. 1. In FIG. 2, the back electrode 217a is formed by a first layer 225 of MoNₓ material, which is deposited on the ZnTe or Cu-doped ZnTe interface layer 213, and a second layer 227 of Mo, which is deposited on the MoNₓ first layer 225. The back electrode 217a may include a metal layer 231 deposited over the Mo layer 227. FIG. 5 illustrates a series of processing chambers 503, 505, 507, 509, and 511 which can be used to form the interface layer 213 of ZnTe or Cu-doped ZnTe, the MoNₓ layer 225, and the Mo layer 227 on a partially completed PV device structure 401. The partially completed PV device 401 includes, as in the FIGS. 1, 4 and 4A embodiments, all layers illustrated in FIG. 1 and FIG. 2 up to and including the absorber layer 211.

Before entering chamber 503, the absorber layer 211 may be pre-cleaned. As shown in FIGS. 5 and 5A, the processing sequence to form the FIG. 2 embodiment employs two separation chambers 505 and 509, a ZnTe (or Cu-doped ZnTe) deposition chamber 503, an MoNₓ deposition chamber 507 and an Mo deposition chamber 511. The two separation chambers 505 and 509 are respectively provided between the ZnTe (or Cu-doped ZnTe) processing chamber 503 and the MoNₓ processing chamber 507 and between the MoNₓ processing chamber 507 and the Mo processing chamber 511. The gas separation chambers 505 and 509 prevent gas and material cross contamination between chambers 503 and 507 and between chambers 507 and 511.

As illustrated in the FIG. 5A processing sequence, the partially completed photovoltaic device 401 first passes into processing chamber 503 where the interface layer 213 is deposited on absorber layer 211 in the manner described above with respect to FIGS. 4 and 4A. Step 551 in FIG. 5A. The interface layer 213 can be a ZnTe layer or a copper doped ZnTe layer.

After the ZnTe or Cu-doped ZnTe interface layer is formed on the absorber layer 211, the partially completed PV device 401 passes through the gas separation chamber 505. Step 553 in FIG. 5A. From there the partially completed PV device passed into the MoNₓ processing chamber 507 in which MoNₓ layer 225 (FIG. 2) is deposited on the ZnTe or Cu-doped ZnTe interface layer 213. The MoNₓ layer 225 may be deposited in chamber 507 by sputtering, in which an argon (Ar) or other ionizing inert gas, and nitrogen gas (N₂) are used to sputter the Mo target. The processing conditions in processing chamber 507 may include providing an Ar/N₂ gas ratio of about 50 percent N₂ to about 90 percent N₂. The power used to ionize the gases, which can be either DC or pulsed DC, can be in the range of about 10 kW to about 15 kW. Higher levels of nitrogen are employed in processing chamber 507, compared with that used in chamber 407 (FIG. 4), because of some intermixing of Ar/N₂ from the processing chamber 507 into the two separation chambers 505 and 509 compared to only one in FIG. 4. After the MoNₓ layer 225 (FIG. 2) is deposited on the ZnTe or Cu-doped ZnTe interface layer 213, the partially completed PV device 401 passes through gas separation chamber 509 and then into Mo deposition chamber 511. See steps 555 and 557 in FIG. 5A. In deposition chamber 511, an Mo layer 227 is deposited on the MoNₓ layer 225. Here argon (Ar) or any other ionizing inert gas is used to sputter a Mo target resulting in the deposition of Mo. See step 559 of FIG. 5A. The Mo layer 227 may alternatively be formed by any other suitable deposition process known in the art, including, but not limited to, pulse laser deposition (PLD), chemical vapor deposition (CVD), atomic layer deposition (ALD), or vapor transport deposition (VTD). Following deposition of Mo layer 227, the partially completed PV device 401 may be transported to a chamber 513 where a metal layer 231 may be deposited over the Mo layer 227 to form the completed back electrode 217a. The metal layer 231 may be formed of the same metals as described above for the FIG. 1 embodiment.

The embodiment of FIG. 2 has a benefit over that of FIG. 1 embodiment in that the sheet resistance of the back electrode 217a is lowered and is in the range of 100-150 ohm-sq.

FIG. 3 illustrates a third embodiment of a PV device 105 and FIGS. 6, 6A respectively illustrate the processing chambers and processing sequence for forming it. In this embodiment, the MoNₓ and Mo layers 225 and 227 shown in FIG. 2 are reversed such that the Mo layer 227 is in contact with the interface layer 213 of ZnTe or Cu-doped ZnTe and the MoNₓ layer 225 is in contact with the Mo layer 227. The remaining material layers 201, 203, 205, 207, 209 and 211 shown in FIG. 3 are the same as those described above with reference to FIGS. 1 and 2.

Referring to FIGS. 6 and 6A, the processing chambers and processing sequence for forming the FIG. 3 embodiment are now described. A partially completed PV device 401, as described above, includes all material layers up to and including the absorber layer 211, which may be pre-cleaned. The partially completed PV device 401 passes through a series of processing chambers including a ZnTe (or Cu-doped ZnTe) deposition chamber 603, a Mo deposition chamber 605, a gas separation chamber 607, and a MoNₓ deposition chamber 609. The processing chamber 603 deposits the interface layer 213 ZnTe or Cu-doped ZnTe on absorber layer 211 in the manner described above with respect to chambers 403 (FIG. 4) and 503 (FIG. 5). Step 651 of FIG. 6A. Following this, the partially completed PV device 401 passes through the Mo deposition chamber 605 where a layer of Mo is deposited on the interface layer 213. The deposition of the Mo layer follows the same procedure as described above with respect to chamber 511 (FIG. 5). Step 653 of FIG. 6A. The partially completed PV device 401 next passes through the gas separation chamber 607. Step 655 of FIG. 6A. The partially completed PV device 401 next passes through the MoNₓ deposition chamber 609 where a layer of MoNₓ 225 is formed over the Mo layer 227. Step 657 of FIG. 6A. the processing in chamber 609 is the same as the processing which occurs in chamber 407 (FIG. 4) or chamber 507 (FIG. 5). The Ar/N₂ ratio in chamber 609 can be in the range of about 30 percent N₂ to about 75 percent N₂ and the power used to ionize the gases, which can be either DC or pulsed DC, can be in the range of about 8 kw to about 12 kw. Following the MoNₓ deposition in chamber 609, the partially completed PV device may pass into a metal deposition chamber 611 which operates the same as chambers 409 (FIG. 4) and 513 (FIG. 5) to deposit a metal layer 231 over the MoNₓ layer 225 of the same metals as described above for layer 231, thus completing the back electrode 217b.

The FIG. 3 embodiment has the advantage of having the Mo layer 227 protected by the MoNₓ layer 225 which can partially diffuse into the Mo layer 227 and/or provide a moisture barrier for the Mo layer 227.

The various embodiments described with respect to FIGS. 1-3 have the advantage of better alignment of the band gap of the materials between the absorber layer 211 and the ZnTe or Cu-doped ZnTe interface layer 213, and between the interface layer 213 and the MoNₓ, Mo/MoNₓ, or MoNₓ/Mo layers.

In addition, the embodiments described allow a manufacturer to provide a wide range of Voc (voltage open current) at the output of the completed PV device as well as a wide range of sheet resistance values for the back electrode. The provisions of MoNₓ, Mo/MoNₓ or MoNₓ/Mo layers over the ZnTe or Cu-doped ZnTe interface also prevents oxidation of the ZnTe or Cu-doped ZnTe when the latter is exposed to atmospheric conditions. In addition, a bilayer structure of Mo/MoNₓ or MoNₓ/Mo provides a good diffusion barrier for other metals in layer 231 which might otherwise diffuse into the absorber layer 211 and which may be provided as the final metal layer in the back electrode structure.

In some instances, it may be desirable to diffuse copper into the absorber layer 211 to form a layer of CdTe:Cu. If such is desired, the copper may come from a copper containing layer, e.g., CdCu deposited on the Mo 227 or MoNₓ (215 or 225) layer, whichever is uppermost in the FIGS. 1-3 embodiments, and can be diffused into the absorber layer 211 by heat treatment in which case the interface layer ZnTe can serve to modulate the amount of Cu which enters absorber layer 211. An interface layer that includes undoped ZnTe followed by Cu-doped ZnTe (bi-layer) may also be used to provide additional modulation of Cu. The copper for doping the absorber layer 211 can instead, or also, come from the copper doping in a Cu-doped ZnTe interface layer 213, again in the presence of a heat treatment.

FIG. 7 shows an embodiment of a PV device 111 which includes a CdTe copper doped absorber layer 211. In FIG. 7, layers 201 through 209 are the same as like layers in the FIGS. 1-3 embodiments. In addition, the dotted line represents any of the back electrodes 217, 217a or 217b described above with respect to FIGS. 1-3. In this embodiment, a cadmium zinc telluride (Cd₁₋ₓZnₓTe) layer (where x is between 0 and 1) is formed between the CdTe absorber layer 211 and the interface layer 213, which can be ZnTe or Cu-doped ZnTe, preferably Cu-doped ZnTe. The Cd₁₋ₓZnₓTe layer is doped with copper. As noted, the Cu doping can come from a copper containing layer deposited over the layers 215 (FIG. 1), 227 (FIG. 2), and 225 (FIG. 3) before the metal layer 231 is applied if desired. However, more preferably the copper can come from a Cu-doped ZnTe interface layer 213. The addition of a copper doped Cd₁₋ₓZnₓTe layer 212 has several advantages. Since the copper doping can originate from a Cu-doped ZnTe interface layer 213, there is no need to separately synthesize a copper doped Cd₁₋ₓZnₓTe layer. The copper doped Cd₁₋ₓZnₓTe layer 212 forms a graded p++ layer which can be engineered to have a diffusion profile which is modulated by the Cd₁₋ₓZnₓTe composition to form a desirable transition from the CdTe absorber layer 211 to the Cu-doped ZnTe interface layer 213 which can minimize lattice mismatch problems at the CdTe/ZnTe interface and reduce the presence of charge recombination sites at the interface.

While various structural and method embodiments have been described and illustrated, the invention is not limited by the described embodiments, but is only limited by the scope of the appended claims.

What is claimed is:

1. A photovoltaic device comprising:
an absorber layer;
an interface layer comprising ZnTe; provided over the absorber layer; and
a back electrode comprising a MoNₓ layer provided over the ZnTe interface layer.

2. The photovoltaic device of claim 1, wherein the back electrode further comprises a Mo layer.

3. The photovoltaic device of claim 1, wherein the ZnTe interface layer is doped with Cu.

4. The photovoltaic device of claim 2, wherein the MoNₓ layer is disposed between the ZnTe interface layer and the Mo layer.

5. The photovoltaic device of claim 2, wherein the Mo layer is disposed between the ZnTe interface layer and the MoNₓ layer.

6. The photovoltaic device of claim 1, further comprising a window layer below the absorber layer, and wherein the window layer comprises CdS and the absorber layer comprises CdTe.

7. The photovoltaic device of claim 1, wherein the MoNₓ layer comprises Mo₃N₂.

8. The photovoltaic device of claim 1, wherein the MoNₓ layer comprises Mo₂N.

9. The photovoltaic device of claim 1, wherein the MoNₓ layer comprises MoN.

10. The photovoltaic device of claim 1, wherein the back electrode has a sheet resistance in the range of about 100 to about 300 ohm-sq.

11. The photovoltaic device of claim 1, wherein the back electrode further comprises a metal layer over the MoNₓ layer.

12. The photovoltaic device of claim 11, wherein the metal layer comprises a metal selected from one or more members of the group consisting of aluminum, copper, nickel, gold, silver, or chromium.

13. The photovoltaic device of claim 1, further comprising a Cd₁₋ₓZnₓTe layer between the absorber layer and the ZnTe interface layer.

14. The photovoltaic device of claim 13, wherein the Cd₁₋ₓZnₓTe layer is doped with copper.

15. The photovoltaic device of claim 14, wherein the ZnTe interface layer is doped with copper.

16. A method of forming a back electrode of a photovoltaic device comprising:
forming a ZnTe material over an absorber layer; and
forming a back electrode comprising a MoNₓ material over the ZnTe material.

17. A method as in claim 16, further comprising forming a Mo material as part of said back electrode.

18. A method as in claim 16, further comprising forming a metal material over the MoNₓ material as part of the back electrode.

19. A method as in claim 16, further comprising doping the ZnTe material with Cu.

20. A method as in claim 17, wherein the MoNₓ material is formed between the ZnTe material and the Mo material.

21. A method as in claim 17, wherein the Mo material is formed between the ZnTe material and the MoNₓ material.

22. A method as in claim 16, further comprising forming a Cd₁₋ₓZnₓTe layer between the absorber layer and the ZnTe material.

23. A method as in claim 22, where the Cd₁₋ₓZnₓTe layer is doped with copper.

24. A method as in claim 23, wherein the ZnTe material is doped with copper.

25. A method of forming a back electrode of a photovoltaic device, comprising:
passing a substrate containing an absorber material on an upper surface through a first deposition chamber and depositing a ZnTe material in said first disposition chamber on the absorber material; and
passing the substrate containing the ZnTe material through a second deposition chamber in which a MoNₓ material is deposited.

26. A method as in claim 25, further comprising passing the substrate including the ZnTe material through a gas separation chamber before passing it to the second deposition chamber.

27. A method as in claim 26, further comprising passing the substrate including the deposited MoNₓ material through a third processing chamber at which a Mo material is deposited.

28. A method as in claim 27, further comprising passing the substrate including the MoNₓ material through a gas separation chamber before passing it through the third processing chamber.

29. A method as in claim 25, further comprising passing the substrate comprising the ZnTe material through a third processing chamber at which a Mo material is deposited before passing the substrate containing the ZnTe material through the second processing chamber.

30. A method as in claim 29, further comprising passing the substrate containing the Mo material through a gas separation chamber before passing the substrate through the second processing chamber.

31. A method as in claim 25, further comprising doping the deposited ZnTe material with copper.

32. A method as in claim 25, further comprising forming a window layer below the absorber layer, and wherein the window layer comprises CdS and the absorber layer comprises CdTe.

33. A method as in claim 25, wherein the MoNₓ material comprises Mo₃N₂.

34. A method as in claim 25, wherein the MoNₓ layer comprises Mo₂N.

35. A method as in claim 25, wherein the MoNₓ layer comprises MoN.

36. A method as in claim 25, further comprising forming a metal layer over the MoNₓ layer.

37. A method as in claim 36, wherein the metal layer comprises a metal selected from one or more members of the group consisting of: aluminum, copper, nickel, gold, silver, or chromium.

38. A method as in claim 25, wherein the ZnTe material is deposited by sputtering.

39. A method as in claim 25, wherein the MoNₓ material is deposited by sputtering.

40. A method as in claim 27, wherein the Mo material is deposited by sputtering.

41. A method as in claim 29, wherein the Mo material is deposited by sputtering.
